(19) United States
(12) Patent Application Publication
(10) Pub. No.: US 2014/0054609 A1
(43) Pub. Date: Feb. 27, 2014

(54) LARGE HIGH-QUALITY EPITAXIAL WAFERS

(71) Applicant: CREE, INC., Durham, NC (US)

(72) Inventors: Albert Augustus Burk, Chapel Hill, NC (US); Michael O'Loughlin, Chapel Hill, NC (US)

(73) Assignee: Cree, Inc., Durham, NC (US)

(21) Appl. No.: 13/785,192

(22) Filed: Mar. 5, 2013

Related U.S. Application Data
(60) Provisional application No. 61/693,298, filed on Aug. 26, 2012.

(51) Int. Cl. H01L 21/322; H01L 29/32

(52) U.S. Cl. CPC H01L 21/3221; H01L 29/32
USPC 257/77; 438/477

(57) ABSTRACT

Large high-quality epitaxial wafers are disclosed. Embodiments of the invention provide silicon carbide epitaxial wafers with low basal plane dislocation (BPD) densities. In some embodiments, these wafers are of the 4H polytype. These wafers can be at least about 100 mm in diameter and have an epitaxial layer from about 1 micron to about 300 microns thick. In some embodiments the wafers include an epitaxial stack with a buffer layer and a drift layer and the (BPD) density in the drift layer is less than about 2 cm⁻². A wafer according to embodiments of the invention can be made by placing an SiC substrate wafer in a reactor and using a facile step flow to cause a majority of ad-atoms to be coincident with an edge or kink of an atomic step on a surface of the SiC substrate wafer.

### CROSS-REFERENCE TO RELATED APPLICATION

This application claims priority from commonly-owned, co-pending U.S. provisional application Ser. No. 61/693,298 filed Aug. 26, 2012, the entire disclosure of which is hereby incorporated herein by reference.

### BACKGROUND

Semiconductor devices are typically fabricated on a substrate that provides mechanical support for the device and often contributes to the electrical performance of the device as well. Silicon, germanium, gallium arsenide, sapphire and silicon carbide are some of the materials commonly used as substrates for semiconductor devices. Many other materials are also used as substrates. Semiconductor device manufacturing typically involves fabrication of many semiconductor devices on a single substrate.

Substrates are often formed in the shape of circular wafers. Other shapes such as for example square, rectangular or triangular wafers exist. Semiconductor devices are formed on the wafers by the precise formation of thin layers of semiconductor, insulator and metal materials which are deposited and patterned to form useful semiconductor devices such as diodes, transistors, solar cells and other devices.

Semiconductor crystals can be produced by a number of techniques. For example, in a typical silicon carbide crystal growth technique, a seed crystal and a source material are both placed in a reaction crucible which is heated to the sublimation temperature of the source and in a manner that produces a thermal gradient between the source and the marginally cooler seed crystal. The thermal gradient encourages vapor phase movement of the materials from the source to the seed followed by condensation upon the seed and resulting bulk crystal growth. The method is sometimes referred to as physical vapor transport (PVT).

A bulk single crystal of semiconductor material may then be desirably cut into wafers and polished prior to the growth of epitaxial layers and the formation of devices on the wafers as described above. Various types of defects may be present in the wafers. Such defects may have been present in the bulk crystal, or may be introduced in post-growth processing. For example, mechanical polishing of the wafers can leave defects. Defects can also occur in the epitaxial layers. These defects may result from underlying defects in the wafers or may be introduced during epitaxial growth. The larger the diameter of the wafers, the more difficult it is to prevent defects from forming in both the substrate wafers and the epitaxial layers.

### SUMMARY

Embodiments of the invention provide low basal plane dislocation (BPD) silicon carbide (SiC) epitaxial wafers. In some embodiments, these wafers are single crystal wafers and in some embodiments, these wafers are of the 4H polytype. The epitaxial layer can be a doped layer of the same polytype of silicon carbide as the substrate. These wafers can be at least about 100 mm in diameter. These low BPD materials enable superior material properties for SiC bipolar power devices.

A silicon carbide wafer according to some embodiments of the invention has a diameter of at least 100 mm and an epitaxial layer from about 1 micron to about 300 microns thick, wherein a basal plane dislocation (BPD) density in at least a portion of the epitaxial layer is less than about 2 cm⁻². In some embodiments, the epitaxial layer is from about 1 to about 50 microns thick. In some embodiments the wafer is between about 100 and about 300 mm in diameter and the epitaxial layer is between about 25 microns and about 35 microns thick, with the BPD density being between about 0.5 cm⁻² and about 2 cm⁻². In some embodiments the wafer has a diameter between about 100 and about 200 mm and the BPD density is less than about 1 cm⁻².

In some embodiments of the epitaxial wafers, the density of basal plane dislocations in the epitaxial layer capable of causing forward voltage drift in devices made from the silicon carbide wafer is from about 0.05 cm⁻² to about 0.2 cm⁻². In some embodiments, the density of basal plane dislocations in the epitaxial layer capable of causing forward voltage drift in devices made from the silicon carbide wafer is less than about 0.1 cm⁻². Some embodiments of the epitaxial wafers described herein also include a buffer layer from about 0.5 and about 15 microns thick. The buffer layer in such embodiments is disposed between a silicon carbide substrate and the main epitaxial layer. The main epitaxial layer can sometimes be referred to as a “drift layer” to distinguish it from the buffer layer.

In some embodiments of the invention, a semiconductor wafer includes a silicon carbide substrate having a diameter from about 100 mm to about 300 mm, and an epitaxial stack on the silicon carbide substrate, where the epitaxial stack is from about 1 micron to about 300 microns thick. The epitaxial stack includes the drift layer with a basal plane dislocation (BPD) density less than about 2 cm⁻². In some embodiments, the epitaxial stack is between about 5 microns and about 100 microns thick and in addition to the drift layer includes a buffer layer having a thickness between about 0.5 microns and about 10% of the entire thickness of the epitaxial stack. In some embodiments one or more of the silicon carbide substrate and all or part of the epitaxial stack includes silicon carbide of the 4H polytype.

The semiconductor wafers according to some embodiments of the invention can be between about 150 mm and about 250 mm in diameter. In some embodiments, the epitaxial layer, the drift layer, or the epitaxial stack is between about 1 micron and about 50 microns thick. In some embodiments of the epitaxial wafers, the density of basal plane dislocations in the drift layer capable of causing forward voltage drift in devices made from the wafer is about 0.2 cm⁻².

Epitaxial wafers according to some embodiments of the invention can be made by growing a silicon carbide crystal and slicing the silicon carbide crystal to produce a silicon carbide (SiC) substrate wafer. In some embodiments this SiC crystal is a single crystal grown using a PVT process. The SiC substrate wafer can then be placed in a reactor, and a facile step flow is initiated to cause a majority of ad-atoms that are to form a part of the epitaxial to be coincident with an edge or kink of an atomic step on a surface of the SiC substrate wafer. The epitaxial layer is ultimately grown to its final thickness and in some embodiments has or includes a basal plane dislocation (BPD) density less than about 2 cm⁻².

In some embodiments, the epitaxial layer and/or the epitaxial stack is grown in a hot wall reactor. However, in some embodiments, a warm wall reactor can be used. In some embodiments, a buffer layer is also grown, wherein the buffer layer is more highly doped than the drift layer.

### BRIEF DESCRIPTION OF THE DRAWINGS

FIG. 1 is a plot showing BPD characteristics of various wafers, including wafers according to example embodiments of the present invention.

FIG. 2 is a portion of a cross-section of a wafer according to example embodiments of the present invention. The wafer of FIG. 2 has been processed to the point of having some device features.

FIG. 3 is a graph of basal plane dislocations for a wafer according to example embodiments of the invention.

FIG. 4 illustrates the growth of a silicon carbide crystal used to make epitaxial wafers according to example embodiments of the invention.

FIG. 5 illustrates a substrate wafer according to example embodiments of the invention being processed in a hot wall reactor.

FIG. 6 is a schematic illustration of facile step flow causing ad-atoms to be coincident with an edge or kink of an atomic step on a surface of an SiC substrate wafer, which is part of the process for making wafers according to example embodiments of the invention.

FIG. 7 illustrates an epitaxial wafer according to example embodiments of the invention undergoing further processing in the reactor of FIG. 5.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Unless otherwise expressly stated, comparative, quantitative terms such as “less” and “greater”, are intended to encompass the concept of equality. As an example, “less” can mean not only “less” in the strictest mathematical sense, but also, “less than or equal to.”

Embodiments of the invention provide low basal plane dislocation (BPD) silicon carbide (SiC) epitaxial wafers. In some embodiments, these wafers are single crystal wafers and in some embodiments, these wafers are of the 4H polytype. In some embodiments, the epitaxial layer is a doped layer of the same polytype of silicon carbide. These wafers can be at least about 100 mm in diameter. In some embodiments, the wafers can be at least about 150 mm in diameter. In some embodiments, the wafers can be from about 100 mm to about 200 mm in diameter. In some embodiments, the wafers can be from about 100 mm to about 250 mm in diameter. In some embodiments, the wafers can be from about 150 mm to about 200 mm in diameter. In some embodiments, the wafers can be from about 150 mm to about 250 mm in diameter. In some embodiments, the wafers can be from about 100 mm to about 150 mm in diameter. In some embodiments, these wafers can be from about 100 mm to about 300 mm in diameter. In some embodiments, the wafers can be from about 150 mm to about 300 mm in diameter.

There are two BPD densities that are discussed relative to the wafers and devices described herein. One is a total density, and the other is the density for a typically smaller number of BPDs that are capable of causing voltage drift in a finished device. The epitaxial material in some embodiments exhibits a total BPD density less than about 1 cm⁻² in the drift layer, with BPDs capable of causing V_{f} (forward voltage) drift as low as about 0.1 cm⁻². In some embodiments the material exhibits a total BPD density less than about 2 cm⁻² in the epitaxial layer, with BPDs capable of causing V_{f} drift as low as 0.1 cm⁻². In some embodiments the total BPD density is between about 0.5 cm⁻² and about 2 cm⁻². BPDs capable of causing V_{f} drift in some embodiments can be between about 0.05 cm⁻² and about 0.2 cm⁻². In some embodiments, the density of BPDs in the epitaxial layer that are capable of causing V_{f} drift can be between 0 cm⁻² and 0.1 cm⁻². In some embodiments the total BPD density can be between about 0.5 cm⁻² and about 1 cm⁻². It should be noted that a density per unit of area may be expressed as either a number followed by units⁻², or a number/units².

These low BPD materials enable superior material properties for SiC bipolar power devices. In some embodiments, the epitaxial layer can be between about 1 micron and about 50 microns thick. In some embodiments, the epitaxial layer can be between about 25 microns and about 35 microns thick. In some embodiments, the epitaxial layer can be about 30 microns thick. In some embodiments, the epitaxial layer can be less than 50 microns thick and greater than 1 micron thick. In some embodiments, the epitaxial layer can be less than 20 microns thick and greater than about 1 micron thick. In some embodiments, the epitaxial layer can be between about 1 micron thick and about 300 microns thick. In some embodiments, the epitaxial layer can be between about 25 microns thick and about 300 microns thick. In some embodiments, the epitaxial layer can be from about 5 microns to about 100 microns thick or about 5 microns to about 300 microns thick.

In some embodiments, the epitaxial layer is grown on a buffer layer. In some embodiments, the buffer layer can be between about 0.5 microns and about 1.5 microns thick. In some embodiments, the buffer layer can be about 1 micron thick. In some embodiments, the buffer layer can be between about 0.5 microns and about 15 microns thick. In some embodiments, the buffer layer can be between about 0.5 microns thick and a thickness that is 10% of the thickness of the full epitaxial stack, which is the combination of the buffer layer and the drift layer. The buffer layer may be made of epitaxial material that is differently doped than the epitaxial layer referred to above, which may also sometimes be referred to as the drift layer or the low-doped layer. For example, the buffer layer may be made of more highly doped material. The thicker epitaxial layer is sometimes referred to as the “drift layer” because this is the layer where the charge carriers “drift” as driven by the electric field in the device. In a finished device, the drift layer may occupy the space between the buffer layer and any devices or contacts. The example thicknesses herein may specify only the drift layer or the entire epitaxial stack and either may also be referred to as the epitaxial layer or layers.

The highest power semiconductor devices operate in a bipolar conductivity mode. Historically, basal plane dislocations have been correlated to device degradation in specific bipolar devices, causing V_{f} drift and limiting device yield. Low BPD material according to embodiments of the invention can reduce this dislocation density and enable improved yields and reduced costs. Low BPD epitaxial wafers according to embodiments of the invention can be used to produce a broad range of power, and communication components, including power switching devices, and RF power transistors for wireless communications.

At least some embodiments of the invention provide a high quality, low micropipe silicon carbide epitaxial wafer with a diameter of at least about 150 mm, wherein the epitaxial layer extends substantially across the entire wafer. Such a wafer may include a buffer layer as previously described. In some embodiments, the wafer is a single crystal wafer. In some embodiments, the wafer is of the 4H polytype. In some embodiments, the wafer is of the N carrier type. In some embodiments, these wafers have epitaxial layers at least about 100 microns thick. In some embodiments, the wafers have an epitaxial layer between about 50 microns and about 150 microns thick. In some embodiments, the wafers have an epitaxial layer between about 75 microns and about 125 microns thick. In some embodiments, these wafers can have an epitaxial layer between about 50 microns and about 300 microns thick. In some embodiments these wafers are from about 100 mm to about 200 mm in diameter. In some embodiments, these wafers are from about 150 mm to about 250 mm in diameter or from about 100 mm to about 250 mm in diameter. In some embodiments, these wafers can be from about 100 mm to about 300 mm in diameter.

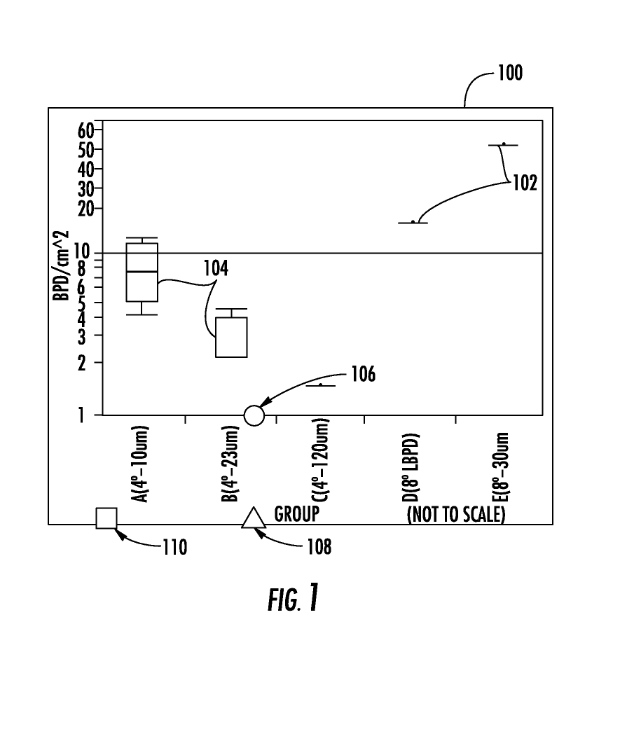

FIG. 1 is a plot 100 showing BPD characteristics of various wafers. BPDs can be measured by KOH/NaOH eutectic etching and observation of the pits formed, or by UV laser pumping of near IR BPD defect luminescence (UVPL). UVPL measures only BPDs in the drift layer since only these BPDs luminesce. BPDs with built-in stacking faults in the epitaxial layer are not shown by UVPL, but these BPDs also do not cause forward voltage drift. With embodiments of the invention, very few BPDs make it through the buffer layer of the epitaxial wafer because of efficient conversion from BPDs to threading edge dislocations. In FIG. 1, features 102 show BPDs for 8-degree off-axis epitaxial wafers as measured by eutectic etch pits. Features 104 indicate BPDs for 4-degree off-axis epitaxial wafers produced in the conventional manner, as measured by eutectic etch pits. Dot 106 indicates total BPD pit densities obtained with an embodiment of the invention with a 30 micron epitaxial layer and a 1 micron N+ buffer layer. Triangle 108 indicates the isolated BPD densities measured by eutectic etch pits (about 0.1 cm⁻²). These are BPDs that could cause forward voltage drift. Box 110 indicates isolated BPD densities above the one micron buffer layer as measured by UVPL.

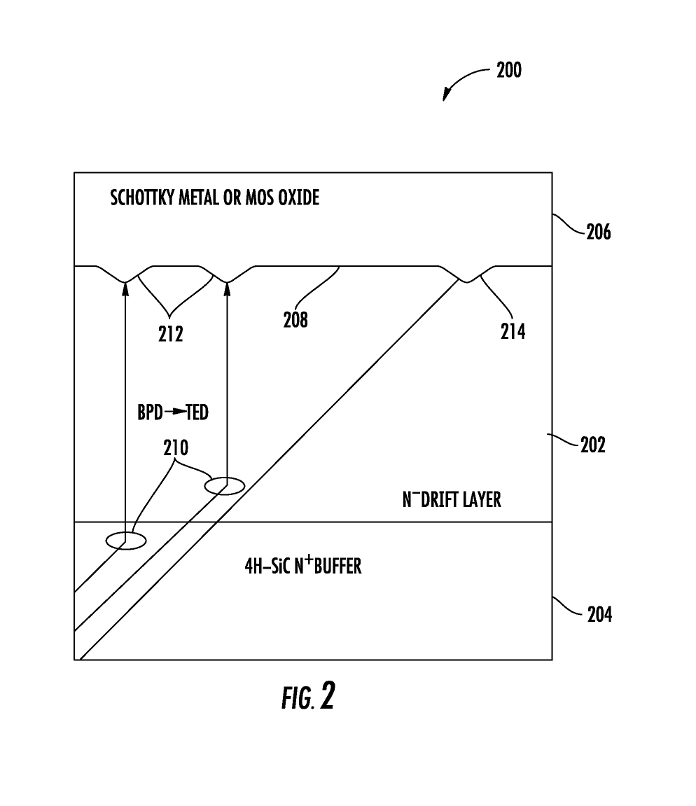

FIG. 2 is a cross-section 200 of a wafer according to example embodiments of the invention with some devices. Layer 202 in FIG. 2 is an N− drift layer. Layer 204 is the buffer layer. Layer 206 is the device layer, which includes metal and/or oxide depending on what portion of the device is present in the cross-section, and is above the epitaxial surface 208. Only isolated BPDs above the buffer are seen by the UVPL technique. BPDs in the device layer can cause forward voltage drift in devices. Only drift layer BPDs luminesce in UVPL measurement. BPDs in built-in stacking faults are not seen by UVPL, but do not cause voltage drift. Often a BPD such as BPDs 210 is converted to a threading edge dislocation (TED) in the buffer layer and does not make it into the drift layer to cause voltage drift. In some embodiments of the invention, almost all BPDs are converted to TEDs in the buffer layer. TEDs can form eutectic etch pits such as TED etch pits 212 and a BPD can form a eutectic etch pit such as BPD etch pit 214.

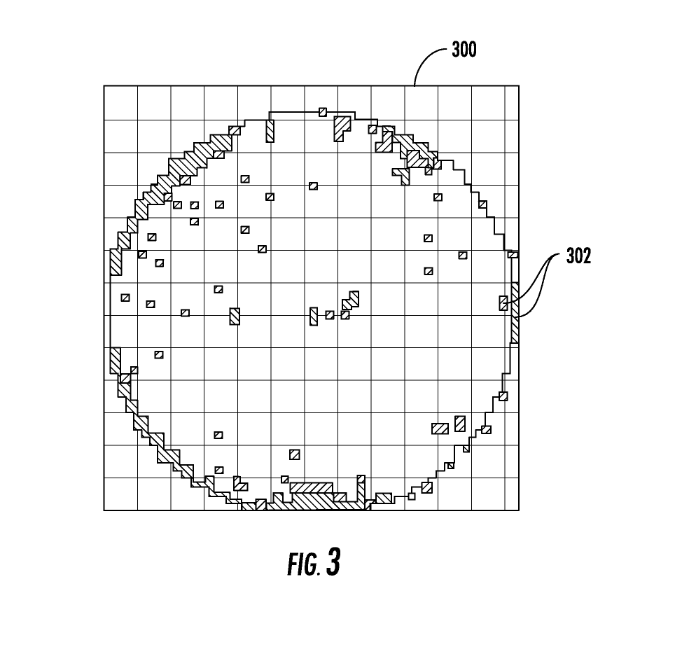

FIG. 3 is a UVPL graph 300 that indicates 78% of a wafer according to embodiments of the invention is free of any BPDs throughout the drift layer thickness. This measurement is consistent with a measurement that would be taken by eutectic etch that showed 90% of the surface is free of etch pits. The hatched portions 302 indicate areas where a BPD survives to transit a substantial portion (⅓ or more) of the drift layer.

Epitaxial wafers as described above are produced by providing improved epitaxial atomic step flow conditions for optimizing the epitaxial layer morphology. Such improved epitaxial atomic step flow conditions reduce BPD densities. BPDs, particularly isolated ones that are not part of a “built-in” stacking fault in the epitaxial layer can be sources of growing other stacking faults and the growth of stacking faults causes unwanted forward voltage drift. In some embodiments of the invention, the epitaxial layers on the wafers are produced using a warm wall reactor process. In some embodiments, the epitaxial layers are produced using a hot wall reactor process. A facile step flow is created to ensure that as many of the atoms as possible from the initial portion of the epitaxial layer touch an edge or kink of an atomic step on the surface of the substrate wafer. The atoms that are initially deposited in forming the epitaxial layer are sometimes referred to as “ad-atoms.” In some embodiments, epitaxial wafers according to example embodiments of the invention may have less than 0.1 cm⁻² BPDs in 30 microns of growth and less than 1 cm⁻² BPDs with an epitaxial layer only 1 micron thick. BPDs may also be between 0 cm⁻² and 1 cm⁻².

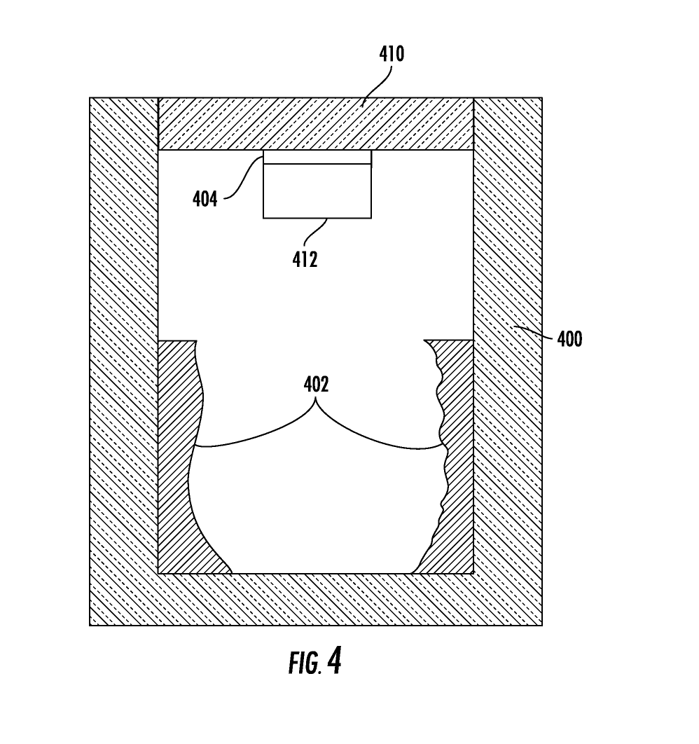

FIG. 4 illustrates the initial part of the process of producing epitaxial wafers according to embodiments of the invention. In FIG. 4, crucible 400 contains SiC source material 402. Crucible 400 includes a seed crystal 404 fastened to crucible lid 410. The crucible is heated and crystal growth takes place until a cylindrical, grown crystal 412 (sometimes referred to as a boule) is fully formed through a PVT process. The crystal in FIG. 4 is shown part-way through the growth process, and the drawing is schematic in nature so that features are not necessarily to scale. The same can be said about all drawings herein. Once crystal 412 is fully formed it can be sliced into SiC substrate wafers. In this example, the SiC wafers are single crystal wafers between about 100 mm and about 300 mm in diameter.

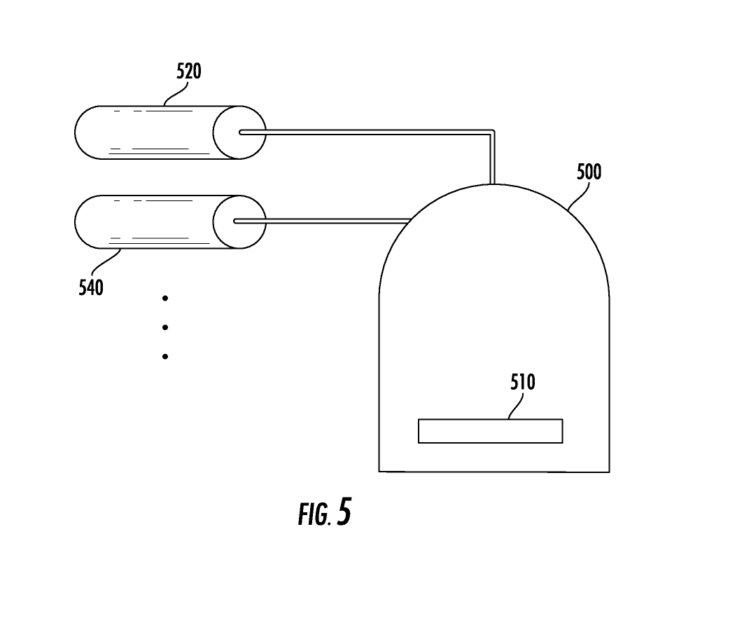

FIG. 5 depicts a reactor 500, which can be used to grow epitaxial layers on SiC substrate wafers. As shown in FIG. 5, a substrate wafer 510 is placed in the reactor 500. The reactor has a variety of gas feeds including at least one or more for dopant gasses 520 and one or more for the source gases 540 to be used for the epitaxial material, in this case, also SiC. Again, FIG. 5 is a schematic drawing and is not intended to illustrate an actual reactor in detail.

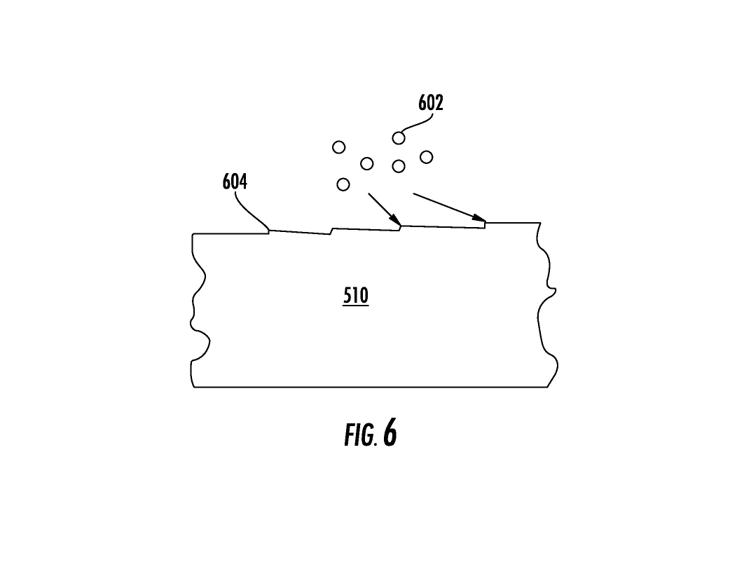

FIG. 6 illustrates the initiation of a facile step flow within reactor 500 of FIG. 5. As shown, ad-atoms 602 migrate towards atomic steps 604 of substrate wafer 510. The atomic steps are shown in exaggerated size in FIG. 6 for clarity. In order to produce the epitaxial wafers described herein, the step flow is adjusted to ensure that as many of the atoms as possible from the initial portion of the epitaxial layer are coincident with an edge or a kink of an atomic step. In some embodiments, at least a majority of the ad-atoms are coincident with an edge or a kink. It should be noted that if an epitaxial layer is grown directly on the substrate wafer, the ad-atoms would touch an edge or a kink. However, if a buffer layer is deposited first, the ad-atoms of the drift layer would touch the resulting step or kink in the intervening buffer layer. These ad-atoms are coincident with an edge or kink in an atomic step of the SiC substrate wafer underlying the buffer layer because the buffer layer follows the contours of the SiC substrate.

A variety of growth conditions can be created and/or adjusted to achieve a facile step flow as described above. For example, growth can be carried out high temperatures. An off-axis substrate can be used to achieve shorter terrace widths. The atomic flux of reagents near the surface of the substrate can also be adjusted to increase the ratio of silicon to carbon being used in the process.

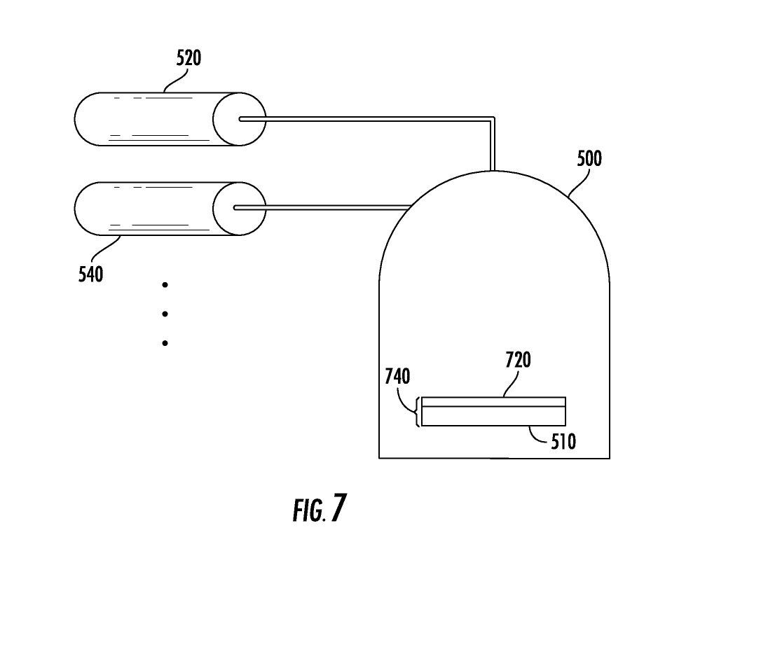

FIG. 7 depicts a reactor 500 at the end of the production of an epitaxial wafer as described herein. In FIG. 7, the complete epitaxial layer or epitaxial stack 720 has been grown on the SiC substrate wafer to produce epitaxial wafer 740. The reactor gas feeds 520 and 540 have been shut off. In this particular example, the epitaxial layer(s) has been grown to a thickness from about 1 micron to about 300 microns. The epitaxial layer(s) is shown in the schematic diagram of FIG. 7 at an exaggerated thickness for clarity. The epitaxial layer in FIG. 7 has a BPD density of less than about 2 cm⁻².

Although specific embodiments have been illustrated and described herein, those of ordinary skill in the art appreciate that any arrangement which is calculated to achieve the same purpose may be substituted for the specific embodiments shown and that the invention has other applications in other environments. This application is intended to cover any adaptations or variations of the present invention. The following claims are in no way intended to limit the scope of the invention to the specific embodiments described herein.

1. A silicon carbide wafer having a diameter of at least 100 mm and an epitaxial layer from about 1 micron to about 300 microns thick, wherein a basal plane dislocation (BPD) density of at least a portion of the epitaxial layer is less than about 2 cm⁻².

2. The silicon carbide wafer of claim 1 wherein the epitaxial layer is from about 1 to about 50 microns thick.

3. The silicon carbide wafer of claim 2 wherein the diameter is between about 100 and about 300 mm, the epitaxial layer is between about 25 microns and about 35 microns thick, and the BPD density is between about 0.5 cm⁻² and about 2 cm⁻².

4. The silicon carbide wafer of claim 3 wherein the diameter is between about 100 and about 200 mm and the BPD density is less than about 1 cm⁻².

5. The silicon carbide wafer of claim 4 wherein the density of basal plane dislocations in the epitaxial layer capable of causing forward voltage drift in devices made from the silicon carbide wafer is from about 0.05 cm⁻² to about 0.2 cm⁻².

6. The silicon carbide wafer of claim 4 wherein the density of basal plane dislocations in the epitaxial layer capable of causing forward voltage drift in devices made from the silicon carbide wafer is less than about 0.1 cm⁻².

7. The silicon carbide wafer of claim 2 further comprising a buffer layer on a surface of a substrate from about 0.5 and about 15 microns thick.

8. The silicon carbide wafer of claim 7 wherein the diameter is between about 100 and about 200 mm and the BPD density is less than about 1 cm⁻².

9. The silicon carbide wafer of claim 8 wherein the density of basal plane dislocations in the epitaxial layer capable of causing forward voltage drift in devices made from the silicon carbide wafer is from about 0.05 cm⁻² to about 0.2 cm⁻².

10. A semiconductor wafer comprising:
a silicon carbide substrate having a diameter from about 100 mm to about 300 mm; and
an epitaxial stack on the silicon carbide substrate, the epitaxial stack being from about 1 micron to about 300 microns thick and further comprising a drift layer with a basal plane dislocation (BPD) density less than about 2 cm⁻².

11. The semiconductor wafer of claim 10 wherein the epitaxial stack is between about 5 microns and about 100 microns thick and further comprises a buffer layer having a thickness between about 0.5 microns and about 10% of the thickness of the epitaxial stack.

12. The semiconductor wafer of claim 11 wherein at least one of the silicon carbide substrate and the epitaxial stack comprises silicon carbide of a 4H polytype.

13. The semiconductor wafer of claim 10 wherein the diameter of the wafer is between about 150 mm and about 250 mm and the epitaxial stack is between about 1 micron and about 50 microns thick.

14. The semiconductor wafer of claim 13 wherein the epitaxial stack further comprises a buffer layer from about 0.5 microns to about 15 microns thick, the buffer layer disposed between the silicon carbide substrate and the drift layer.

15. The semiconductor wafer of claim 14 wherein the BPD density in the drift layer is between about 0.5 cm⁻² and 2 cm⁻².

16. The semiconductor wafer of claim 15 wherein the density of basal plane dislocations in the drift layer capable of causing forward voltage drift in devices made from the semiconductor wafer is less than about 0.2 cm⁻².

17. The semiconductor wafer of claim 16 wherein the density of basal plane dislocations in the drift layer capable of causing forward voltage drift in devices made from the semiconductor wafer is from about 0.05 cm⁻² to about 0.2 cm⁻².

18. The semiconductor wafer of claim 17 wherein the density of basal plane dislocations in the drift layer capable of causing forward voltage drift in devices made from the semiconductor wafer is about 0.1 cm⁻².

19. A method of making an epitaxial wafer, the method comprising:
growing a silicon carbide crystal;
slicing the silicon carbide crystal to produce a silicon carbide (SiC) substrate wafer having a diameter between about 100 mm and about 300 mm;
placing the SiC substrate wafer in a reactor;
initiating a facile step flow to cause a majority of ad-atoms that are to form a part of an epitaxial layer on the SiC substrate wafer to be coincident with an edge or kink of an atomic step on a surface of the SiC substrate wafer; and
growing the epitaxial layer to a thickness from about 1 micron to about 300 microns, wherein at least a portion of the epitaxial layer has basal plane dislocation (BPD) density less than about 2 cm⁻².

20. The method of claim 19 wherein the reactor is a hot wall reactor.

21. The method of claim 20 further comprising growing a buffer layer from about 0.5 microns to about 15 microns thick on the SiC substrate wafer.

22. The method of claim 21 wherein the buffer layer is more highly doped than the portion of the epitaxial layer.

23. The method of claim 22 wherein at least one of the SiC substrate wafer, the epitaxial layer and the buffer layer comprises silicon carbide of a 4H polytype.

24. The method of claim 23 wherein the diameter of the SiC substrate wafer is between about 150 and about 300 mm, the epitaxial layer is between about 1 and about 50 microns thick, and the BPD density is between about 0.5 cm⁻² and about 2 cm⁻².

25. The method of claim 24 wherein the density of basal plane dislocations in the epitaxial layer capable of causing forward voltage drift in devices made from the epitaxial wafer is less than about 0.2 cm⁻².

26. The method of claim 25 wherein the density of basal plane dislocations in the epitaxial layer capable of causing forward voltage drift in devices made from the epitaxial wafer is from about 0.05 cm⁻² to about 0.2 cm⁻².
